(19) United States
(12) Patent Application Publication
(10) Pub. No.: US 2026/0047482 A1
(43) Pub. Date: Feb. 12, 2026

(54) MONOLITHICALLY UNIFIED LOGIC-DISCRETE MEMORY CELL ARRAY SYSTEM ARCHITECTURE

(71) Applicant: ADEIA SEMICONDUCTOR TECHNOLOGIES LLC, San Jose, CA (US)

(72) Inventor: Seung Kang, San Diego, CA (US)

(21) Appl. No.: 18/796,183

(22) Filed: Aug. 6, 2024

(51) Int. Cl. H01L 25/18; H01L 23/00; H01L 25/065; H01L 27/06; H10B 12/00

(52) U.S. Cl. CPC H01L 25/18; H01L 24/83; H01L 25/0657; H10B 12/50; H10D 88/00; H01L 2224/83894; H01L 2924/1431; H01L 2924/1436

(57) ABSTRACT

Disclosed are architectures of semiconductor integrated circuit (IC) device. The semiconductor IC device includes a unified logic die and a memory array die heterogeneously integrated with the unified logic die. The unified logic die includes a compute logic block and a memory the memory logic block monolithically integrated with the compute logic block die on a same substrate. The memory logic block includes a memory peripheral circuitry configured for controlling a memory cell array external to the unified logic die. The memory array die includes the memory cell array, and the memory array die is communicatively coupled with the memory logic block.

### TECHNICAL FIELD

This disclosure generally relates to semiconductor integrated circuit (IC) architectures and more particularly to architectures that include a unified logic and a separately fabricated memory or storage array die that is heterogeneously integrated with the unified logic.

### BACKGROUND

Semiconductor integrated circuit (IC) devices have numerous applications, including consumer electronics, industrial applications, communication applications, and cloud system applications, to name a few. The semiconductor IC device architectures include various types of semiconductor devices and are designed to perform data processing and computation in accordance with commands or instructions for each specific application. The semiconductor devices generally include processing units, such as general-purpose central processing units (CPUs), which are generally adapted for executing one or few instructions at a time, and memory, which is generally adapted for storing data. The semiconductor devices can generally include additional semiconductor components, logic circuitry, processors, and peripheral circuitry to process data based on specific applications. However, in spite of the technological development in the field of semiconductor IC device architecture, a continuing demand for increasing computational resources of the semiconductor IC device architecture poses technical limitations. For example, continuing technological trends of the semiconductor IC device architecture demand increasing miniaturization (e.g., smaller form factor with increasing performance), increasing energy efficiency (e.g., consuming less power and generating less heat), and innovative integration approaches (e.g., combining multiple functions into a single chip to reduce size and cost) of the semiconductor IC device architecture. Accordingly, there is a need for improved semiconductor IC device architecture.

### SUMMARY

In one aspect, a semiconductor integrated circuit (IC) device comprises a unified logic die. The unified logic die comprises a compute logic block and a memory logic block monolithically integrated with the compute logic block on the same substrate. The memory logic block comprises a memory peripheral circuitry configured for controlling a memory cell array external to the unified logic die. The IC device additionally comprises a memory array die heterogeneously integrated with the unified logic die. The memory array die comprises the memory cell array. The memory array die is communicatively coupled with the memory logic block of the unified logic die.

In another aspect, a semiconductor integrated circuit (IC) device comprises a unified logic die. The unified logic die comprises a compute logic block and a memory logic block monolithically integrated with the compute logic block on the same substrate. The memory logic block comprises a memory peripheral circuitry configured for controlling a memory cell array external to the unified logic die. The IC device additionally comprises a memory array die. The memory array die comprises the memory cell array, where the memory array die and the unified logic die are three-dimensionally (3D) integrated by stacking one over the other.

In another aspect, a semiconductor integrated circuit (IC) device comprises a unified logic die. The unified logic die comprises a compute logic block and a memory logic block monolithically integrated with the compute logic block on the same substrate. The memory logic block comprises a memory peripheral circuitry configured for controlling a memory cell array external to the unified logic die. The IC device additionally comprises a memory array die. The memory array die comprises the memory cell array, where the memory array die and the unified logic die are 2.5 dimensionally (2.5D) integrated through an interposer.

In yet another aspect, a semiconductor integrated circuit (IC) device comprises a unified logic die. The unified logic die comprises a compute logic block and a first memory logic block monolithically integrated with the compute logic block on a first substrate. The first memory logic block comprises a first portion of a memory peripheral circuitry comprising at least a memory controller circuitry for accessing the memory cell array during read and write operations. The IC device additionally comprises a memory array die heterogeneously integrated with the unified logic die. The memory array die comprises a memory cell array and a second memory logic block comprising a second portion of the memory peripheral circuitry monolithically integrated with the memory cell array on a second substrate different from the first substrate.

### BRIEF DESCRIPTION OF THE DRAWINGS

The following detailed description of illustrative embodiments, is better understood when read in conjunction with the appended drawings. For the purpose of illustrating the present disclosure, exemplary constructions of the disclosure are shown in the drawings. Moreover, those skilled in the art will understand that the drawings are not to scale. Wherever possible, like elements have been indicated by identical numbers. The detailed description of embodiments and the embodiments set forth in the drawings present various descriptions of specific embodiments of the invention. However, the invention can be embodied in a multitude of different ways. It will be understood that certain embodiments can include more elements than illustrated in a drawing and/or a subset of the elements illustrated in a drawing. Further, some embodiments can incorporate any suitable combination of features from two or more drawings. The present disclosure is not limited to specific methods and apparatus disclosed herein.

FIG. 1 is an example of a conventional semiconductor integrated circuit (IC) device architecture.

FIG. 2A is a schematic diagram of semiconductor IC device architecture, according to an embodiment.

FIG. 2B is a schematic diagram of semiconductor IC device architecture, according to an embodiment.

FIG. 2C is a schematic circuit diagram of a dynamic random access memory cell array fabricated on a memory array die, according to an embodiment.

FIG. 3 is a schematic diagram of semiconductor IC device architecture with two dimensional interconnection, according to an embodiment.

FIG. 4 is a schematic diagram of a modular semiconductor IC device architecture, according to an embodiment.

FIG. 5 is schematic perspective view of an example semiconductor IC device architecture with multi-dimensional bonding, according to an embodiment.

FIG. 6A is an example diagram of 3-dimensionally integrated unified logic die and memory array die, according to an embodiment.

FIG. 6B is an example diagram of 2.5-dimensionally integrated unified logic die and memory array die, according to an embodiment.

FIGS. 7A and 7B illustrate examples of detailed 3D stacking (e.g., 3D bonding) bonding structures.

### DETAILED DESCRIPTION

Although several embodiments, examples, and illustrations are disclosed below, it will be understood by those of ordinary skill in the art that the disclosure described herein extends beyond the specifically disclosed embodiments, examples, and illustrations and includes other uses of the disclosure and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments of the disclosure. In addition, embodiments can comprise several novel features. No single feature is solely responsible for its desirable attributes or is essential to practicing the disclosure herein described.

An industry observation known as Moore's Law, which had predicted a biannual doubling of transistor density in integrated circuits, has fueled the semiconductor industry for the past decades. In accordance with Moore's Law, chipmakers have explored various ways to make transistors ever smaller, resulting in highly integrated monolithic system-on-chip (SoC) designs that combine various functionalities, including computation, wireless communication, audio, etc. However, cost-to-benefit ratio of further scaling has become too high for some applications. As such, a trend in the industry is to adopt IC device architectures in which large, complex SoC is divided and fabricated as smaller chiplets and heterogeneously integrated to build a system for specific applications. Such chiplet-based systems allow for flexible manufacturing by combining separate chips from different vendors and technology nodes instead of designing all functions into one monolithic system on chip. For example, memory cell arrays, which can have relatively low thermal budget and employ different materials relative to CMOS devices formed in silicon, can be separately fabricated and integrated with CMOS devices afterwards. An important consideration for efficient chiplet-based designs is the physical proximity of different chiplets in a common package to ensure fast, high-bandwidth electrical connections therebetween. Two major industry directions for chiplet-based systems include 2.5 dimensional (2.5D) chiplet integration connecting chips side-by-side through a common substrate (also known as an interposer) and three-dimensional (3D) 3D integration, where the chiplets are stacked on top of each other.

### Introduction: Overview of Semiconductor IC Device Architecture

Semiconductor IC device architectures include various semiconductor components, such as semiconductor compute integrated circuit (IC) device components and semiconductor memory system components. The semiconductor compute IC device components include various types of processors and memories. The memories can include random-access memories (RAM) and/or static random-access memories (SRAM). The processors can include general-purpose central processing units (CPUs), which are generally adapted for executing one or few instructions at a time, tensor processing units (TPUs), which may be specially adapted for handling the demanding computations for training neural networks, such as deep learning tasks, and graphics processing units (GPUs), which contain hundreds or thousands of co-processors that compute instructions in parallel. The semiconductor compute IC device components also include various logic circuitry to perform logical operations. Generally, the semiconductor compute IC device components are integrated on a chip or a semiconductor die, such as integrated as a system-on-chip. The semiconductor memory components include stand-alone memories, such as dynamic access memory (DRAM), flash memory, and the like. Generally, such stand-alone memories are composed of massive bit cell arrays, which can store gigabits or terabits of data. The semiconductor memory components also include peripheral circuits to manage the data storage, retrieval, and overall operation of memory cells, such as reading or writing data by accessing each bit cell of the memory cell arrays. For the purpose of description, the semiconductor compute IC device components are referred to as a compute IC device, as disclosed herein. Also, the semiconductor memory components are referred to as a memory system, as disclosed herein. Even though certain semiconductor components or integrated circuits (ICs) are described with respect to various embodiments disclosed herein, the present disclosure does not limit the number and/or types of the semiconductor components. In addition, such numbers and types of semiconductor components can be determined based on specific applications.

The semiconductor IC device can implement the compute IC device and the memory system according to different architectures. In some traditional semiconductor IC device architectures, each of the compute IC devices and the memory system may be fabricated in a disparate substrate. For example, the compute IC device is fabricated in one substrate, and the memory system is fabricated in another substrate, and these two blocks are communicatively coupled via communication interfaces, such as the physical layer (PHY) fabricated in each substrate. However, as the density of the memory cell arrays is increasing with decreasing form factor of the semiconductor system, there is a continuing need in the industry for optimizing the semiconductor IC device architecture to mitigate the memory cell arrays scaling and improve power, performance, area, and cost (PPAC) of the semiconductor system.

To address these and other needs of the semiconductor IC device architecture, aspects of the present disclosure provide various embodiments of a novel semiconductor IC device architecture adapted for chiplet-based designs that efficiently integrate memory and compute functionalities.

In various embodiments, the semiconductor IC device architecture, as disclosed herein, includes a unified logic die that integrates a compute logic block and a memory logic block monolithically on a same substrate. The memory logic block comprises a memory peripheral circuitry configured for controlling a memory cell array external to the unified logic die. At least some of the peripheral circuitry are those that are integrated with the memory cell array in traditional semiconductor memory devices. The compute logic block and the memory logic block are monolithically fabricated on the same substrate to form a unified logic die. The memory cell array is separately fabricated in a disparate substrate, referred to herein as a memory array die. The memory array die is communicatively coupled with the memory logic block through heterogenous integration.

In some embodiments, the unified logic die and the memory array die are heterogeneously integrated with each other. As disclosed herein, heterogeneous integration refers to non-monolithic integration. Heterogeneously integrated unified logic die and the memory array die can include 3 dimensional or 2.5 dimensional integration configurations. In various embodiments disclosed herein, the heterogeneous integration (e.g., the 3 dimensional bonding configuration) can be related to vertically stacked configurations, including directly bonded structures in which the unified logic die and the memory array die can be directly bonded to one another without an intervening adhesive. Such processes and structures are referred to herein as “direct bonding” processes or “directly bonded” structures. Direct bonding can involve the bonding of one material on one element and one material on the other element (also referred to as “uniform” direct bond herein), where the materials on the different elements need not be the same without traditional adhesive materials. Direct bonding can also involve the bonding of multiple materials on one element to multiple materials on the other element (e.g., hybrid bonding in which directly bonded interface includes a metal-to-metal chemically bonded interface and a dielectric-to-dielectric chemically bonded interface).

In some embodiments, the semiconductor IC device architecture, as disclosed herein, can provide a modular architecture configuration by selectively fabricating (e.g., monolithically fabricating) elements of the peripheral circuits on the unified logic die and the memory array die. For example, a portion of memory peripheral circuits, including a memory controller, a memory interface, and clock signal generator elements, can be monolithically fabricated in the unified logic die system. Further, in this example, the remaining elements of the peripheral circuits can be monolithically fabricated as part of the memory array die.

To facilitate an understanding of the systems and methods discussed herein, several terms are described below. These terms and other terms used herein should be construed to include the provided descriptions, the ordinary and customary meanings of the terms, and/or any other implied meaning for the respective terms, wherein such construction is consistent with the context of the term. Thus, the descriptions below do not limit the meaning of these terms but only provide example descriptions.

A central processing unit (CPU) can refer to a processing component that performs the processing of data by executing instructions, such as performing basic arithmetic, logic control, and input/output operations in accordance with the instructions. The CPU can have various architectures that dictate how the CPU processes data, executes instructions and communicates with other parts of the computer system. However, the present disclosure does not limit the CPU architectures.

A tensor processing unit (TPU) can generally refer to a processing unit (e.g., a type of application-specific integrated circuit) specifically designed for accelerating machine learning workloads, such as handling computational requirements of machine learning models (for example, a deep learning algorithm). The TPU can include, without limiting, matrix multiplication units configured to perform matrix multiplications in accordance with the machine learning models, memory configured to support data transfer required for machine learning workloads, and the like.

A neural processing unit (NPU) can generally refer to a processing unit specifically designed for accelerating machine learning and artificial intelligence computations that involve neural networks. For example, the neural network can generally refer to a network having a plurality of nodes and layers, where each node (organized in specific layer(s)) processes data to perform the task, such as data patter reorganization, data classification, output predictions, and the like. The NPU is designed to perform specific types of mathematical operations used in the neural network. The NPU can include a plurality of processing cores configured to execute multiple operations in the neural network parallelly.

A graphics processing unit (GPU) can refer to a processing unit designed to accelerate graphics rendering. The GPU can include a plurality of cores configured to perform parallel processing. The GPU can have various architectures based on required operation, such as parallel processing. In addition, the GPU can be implemented as a stand-alone processing unit or integrated with other processing units, such as the CPU. The present disclosure does not limit the types of GPU architecture and implementation of the GPU.

### Conventional Semiconductor IC Device Architecture

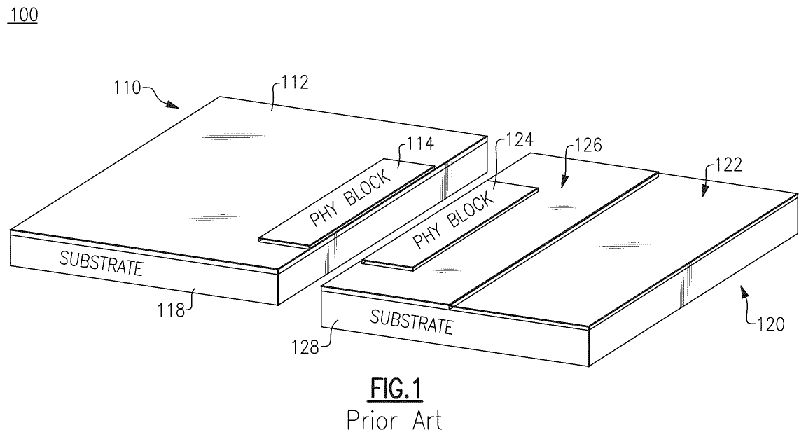

FIG. 1 illustrates a conventional semiconductor IC device architecture 100. As illustrated in FIG. 1, the conventional semiconductor IC device architecture 100 can include a compute IC device 110 and a memory system 120. Each of the compute IC device 110 and the memory system 120 are separately fabricated on substrates 118 and 128, respectively. The compute IC device 110 can include various types of semiconductor components 112, such as a central processing unit (CPU) or a graphic processing unit (GPU). These components can be integrated as one or more silicon on chip (SoC) blocks. The compute IC device 110 also includes a physical block 114. As illustrated in FIG. 1, the semiconductor components 112 and the physical block or layer (PHY) 114 are fabricated on the substrate 118.

As further illustrated in FIG. 1, the memory system 120 includes a memory cell array block 122, a physical block or layer (PHY) 124, and a memory logic block 126. These blocks 122, 124, and 126 are fabricated on a substrate 128. In this conventional semiconductor IC device architecture 100, the compute IC device 110 and the memory system 120 are communicatively coupled via the physical blocks 114 and 124. For example, the CPU included in the compute IC device 110 may read and write data to the memory cells via the physical blocks 114 and 124 and the memory logic block 126.

As used herein, a physical block or layer PHY refers to a communication interface that physically connects devices and serves as the conduit that encodes and/or decodes bits of data communicated between the blocks. That is, the PHY thus refers to a layer that moves data physically, e.g., transmits and receives data over a variety of methods. A PHY can be an IP built into a chip or a dedicated PHY chip. It will be appreciated that a PHY can occupy a significant footprint of the semiconductor IC device. According to embodiments disclosed herein, monolithic integration of the compute IC device 110 and the memory logic block 126 may allow for omission or simplification of the PHY 114 and/or PHY 124.

The inventors have realized that conventional semiconductor IC device architecture 100 can be improved by monolithically integrating at least a portion of the memory logic block 126 as part of the compute IC device 110. For example, the size of the hardware architecture can be reduced greatly by at least eliminating the need for PHY 114 and/or PHY 124. By incorporating both the memory logic block 126 and the memory cell array block 122, the conventional memory system 120 can limit the number of memory cells in the array block 122 due to the available space. Consequently, accommodating Gbits or Tbits of memory cells may necessitate a larger form factor for the hardware architecture. In some conventional semiconductor IC device architectures, the memory logic block 126 can be stacked above the memory cell array block 122. In such architecture, the semiconductor components 112 are communicatively coupled with the memory logic block 126 via the physical blocks 114 and 124, and this configuration poses degradation of system performance due to the communication latency.

### Monolithically Unified Logic Semiconductor IC Device Architecture

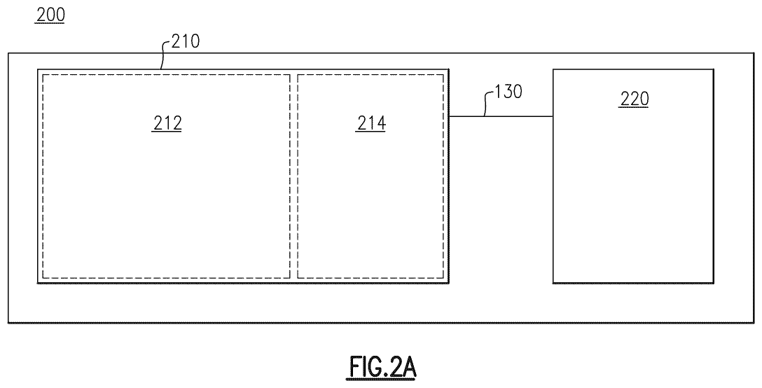

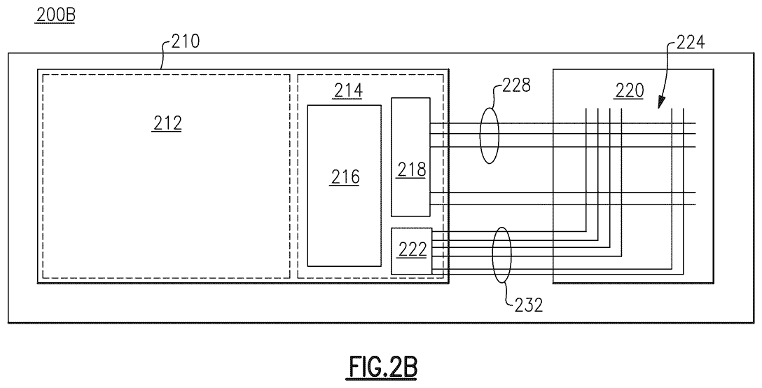

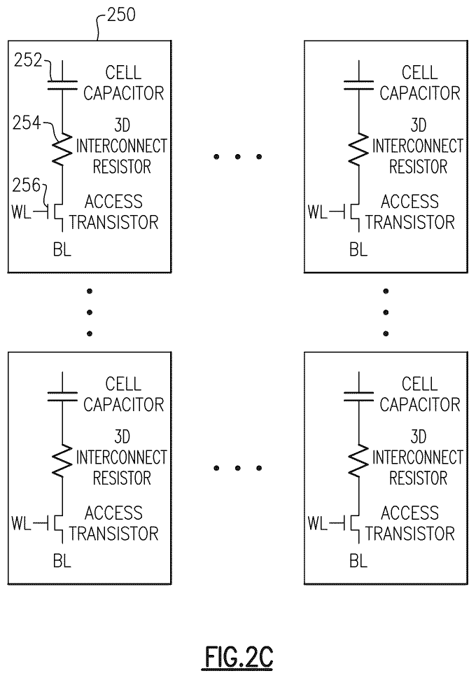

FIG. 2A schematically illustrates a diagram of a novel semiconductor IC device architecture 200 (hereinafter “unified logic architecture 200”), according to embodiments disclosed herein. As illustrated in FIG. 2A, the unified logic architecture 200 can include a unified logic die 210 and a memory array die 220 communicatively coupled via an interconnect 130. The unified logic die 210 can include a compute IC device 212 and a memory logic block 214, where the compute IC device 212 and the memory logic block 214 are monolithically fabricated on a substrate (not shown in FIG. 2A). The compute IC device 212 may contain compute logic block that includes processors and various logic circuitry. For example, the semiconductor processor may include each or any combination of CPU, GPU, NPU, and TPU, and the various logic circuitry can be embedded for executing commands or instructions, such as arithmetic logic unit, control unit, registers, and the like. In some examples, the semiconductor processor can also include cache memory implemented as SRAM. The memory logic block 214 includes memory peripheral circuitry, which includes various circuitry for managing the operation of the memory cell array of the memory array die 220. In some embodiments, the memory logic block 214 manages read/write data operation to or from the memory logic block 214 based on instructions generated from the compute IC device 212. In some examples, the compute logic block and the memory logic block can include co-fabricate circuitry, including complementary metal oxide semiconductor (CMOS) devices co-fabricated on the same substrate. In some embodiments, some of the co-fabricated CMOS devices may be fabricated at a same process technology node and have at least one common critical dimension, e.g., gate length of transistors.

In some embodiments, the compute IC device 212 and the memory logic block 214 are monolithically fabricated on the same substrate (not shown in FIG. 2A). For example, the compute IC device 212 and the memory logic block 214 are communicatively coupled, such that the encoding or decoding of data between the compute IC device 212 and the memory logic block 214 at a physical layer can be omitted. In some embodiments, the memory array die 220 can be a stand-alone memory array die, such that the memory cell array is fabricated on a different substrate (e.g., different substrate from the substrate of the unified logic die 210). The memory array die 220 can include various types of memories, such as dynamic random access memory (DRAM), flash memory, magnetoresistive random access memory (MRAM), resistive random access memory (RRAM or ReRAM), magnetic tunnel junction (MTJ) memory, ferroelectric random access memory (FRAM or FeRAM), phase-change memory (PCM), to name a few. The present disclosure does not limit the number and the types of memory cells. Further, the memory cell array of the memory array die 220 may be two dimensional or three dimensional arrays.

In various embodiments disclosed herein, the memory logic block 214 can include, without limitation, a memory controller, a memory interface, circuitry that controls clock generation, timing signals, read/write operations, refresh (in the case of DRAM), power management, error correction code, etc. In some examples, the memory logic block 214 and the memory array die 220 are communicatively coupled via the interconnect 130, such as through the physically interconnected interface in accordance with various embodiments of the interconnect 130, as disclosed herein. For example, without limitation, the memory logic block 214 can include one or more of the following peripheral circuitry:

Access transistor: An access transistor can be used to access memory locations from the compute IC device 212. An access transistor serially connected to rows or columns may be used to access specific ones of the rows or columns for activating them for read and/or write operations. For example, an access transistor may be disposed between a sense amplifier and bit lines to switch between different ones of the bit lines during sensing. As used herein, access transistors that access one or more rows or columns may be referred to as global access transistors. For example, the access transistor may allow the compute IC device 212 to read from and write data to the memory array die 220 (e.g., designated space in the memory array die 220). It will be appreciated that these global access transistors are distinguishable from access transistors in the array, e.g., an access transistor of a ITIC DRAM cell.

Memory controller: A memory controller is configured to manage the flow of data to and from the memory array die 220. For example, the memory controller functions as an intermediary between the compute IC device 212 and the memory array die 220 to ensure the correct data is read and/or written to/from the memory array die 220 by performing, for example, address translation, data transfer, memory initialization, error detection and correction, and the like.

Memory interface: A memory interface generally refers to a communication interface between the compute IC device 212 and the memory array die 220. For example, the memory controller can be coupled with the compute IC device 212 via the memory interface, thus, the compute IC device 212 can access the memory array die 220 via the memory interface. The memory interface can be a physical or logical connection, having protocols, timing mechanisms, and the like.

Clock signal generator: A clock signal generator generally provides timing signals (e.g., reference timing signals) to the memory array die 220. The timing signals can be utilized as a timing synchronization signal, such that the operation of the memory array die 220 is synchronized with the timing of the compute IC device 212 via the timing signals.

Read/Write operations: Circuitry for read/write operations of the memory array die 220 can generally configured to access and modify data stored in the memory array die 220 (e.g., memory cells of the memory array die 220) from the compute IC device 212. The configuration of the circuitry can be determined based on the types of memory included in the memory array die 220 without limitation.

Refresh (if the memory array die 220 includes DRAM) operations: This circuitry can generally be configured to perform periodically recharging capacitors of the DRAM.

Power management operations: This circuitry can generally be configured to optimize the energy consumption of the memory array die 220. The circuitry can be configured to implement (with limitation) various energy consumption optimization mechanisms, such as voltage and frequency scaling, clock gating, power gating, and the like.

Error correction code: This circuitry is designed to detect and correct errors in data stored in the memory array die 220.

Decoder: The decoder is configured to translate the binary address provided by the compute IC device 212 into outputs, enabling access to the desired memory address of the memory array die 220.

Multiplexer: The multiplexer is configured to select specific memory addresses in the memory array die 220 based on instructions provided by the compute IC device 212.

Sense amplifier: The sense amplifier is configured to detect and amplify the voltage differences stored in memory cells of the memory array die 220. For example, the sense amplifier can detect the voltage differences between the bit lines of the memory array die 220 and amplify the detected voltage differences. Amplifying the voltage differences can ensure an accurate reading of the data.

The memory logic block 214 includes these and other memory peripheral circuitry for supporting various operations of a memory cell array. The memory cell array of the memory array die 220 can include one or more of the following components, depending on the type of memory:
Cell capacitor (if the memory array die 220 includes a DRAM array): The cell capacitor can be utilized to represent state of each cell of the DRAM array by charging or discharging the cell capacitor. For example, a charged cell capacitor represents “1” binary, and a discharged cell capacitor represents “0” binary;
Floating gate/charge trapping layer (if the memory array die 220 includes a flash memory cell array): The floating gate/charge trapping layer can be used to store charge during operation of the flash memory cell array. For example, injecting or removing a charge in the floating gate/charge trapping layer can enable writing, erasing, or reading operations of the flash memory cell array;
Magnetic tunnel junction (if the memory array die 220 includes an MRAM array) the magnetic tunnel junction can be used to store data in the MRAM. For example, the magnetic tunnel junction can include multiple layers, such as free layer, tunnel barrier, and fixed layer. The data, “1” or “0” can be stored based on orientation of magnetic momentum in these layers.

Resistive element (if the memory array die 220 includes RRAM): The resistive element can be used to control operation of the RRAM by changing its resistance state. For example, a resistive switching layer is positioned between two electrode layers. The resistive switching layer can change its resistance when input signal (e.g., voltage) is applied to the two electrodes, such that high resistive state represents “0” where the low resistive state represent “1.”

Ferroelectric capacitor (if the memory array die 220 includes FRAM): The ferroelectric capacitor can store data during the operation of the FRAM. For example, a ferroelectric capacitor layer is positioned between two electrode layers. The ferroelectric capacitor can maintain positive polarization (e.g., representing “1” state) or negative polarization (e.g., representing “0” state), when input signal (e.g., voltage) is applied to the two electrodes.

Phase change element (if the memory array die 220 includes PCM): The phase change element can be used to control operation of the PCM by changing the material property of phase change material used in phase change element.

The memory logic block 214 integrated with the compute IC device 212 includes various features of a memory peripheral circuitry that would have been integrated with a memory cell array in stand-alone memory chips of existing technologies. The periphery circuitry can include, among other things, sense amplifiers, row and/or column drivers, row and/or decoders, and control circuitry. As one illustrative example, FIG. 2B illustrates a DRAM implementation of the semiconductor IC device architecture 200B illustrated in FIG. 2A. In addition to various features described above with respect to FIG. 2A, the semiconductor IC device architecture 200B illustrates additional details in the context of a DRAM implementation.

It will be appreciated that integrating the memory logic block 214 and the computed IC device 212 on the same substrate can provide various manufacturing advantages, including co-fabricating features of the memory logic block 214 with features of the compute IC device 212. For example, in some implementations, MOSFET transistors of the memory logic block 214 and MOSFET transistors of the computed IC device 212 that have common physical characteristics, e.g., dimensions, may be co-fabricated during the same fabrication step(s) or using the same process recipe. For example, transistor features such as source regions, the drain regions, gate electrodes, gate dielectrics, spacers, gate contacts and source and drain contacts of different transistors in the memory logic block 214 and the computed IC device 212 can be at least partly co-fabricated. Under these circumstances, one or more corresponding features including regions or layers may have measurably common attributes, such as physical dimensions, common doping profiles, and common material layers, to name a few. For example, the gates of some MOSFET devices in the memory logic block 214 and the computed IC device 212 may have one or more common physical dimensions including the thickness, gate length or gate width, and/or comprise layers having a common material or thickness. Furthermore, implanted regions such as source and drain regions may have a common doping profile and/or concentration. For example, in some other implementations, one or more metallization features of the memory logic block 214 and the computed IC device 212 may have common physical characteristics, e.g., dimensions, resulting from co-fabrication using the same fabrication step(s) or using the same process recipe. Such metallization features may include metal lines, contacts, and interlayer dielectrics, to name a few.

Referring to FIG. 2B, the array die 220 comprises a memory cell array 224 having formed a plurality of memory cells, represented as intersections between row lines (e.g., word line) 228 and column lines (e.g., a digit or bit lines) 232. Unlike conventional technology, the memory logic block 214 comprising the memory peripheral circuitry is physically separated from the memory cell array 224 and monolithically integrated with the compute IC device 212 as part of the unified logic die 210.

As described herein, the memory peripheral circuitry refers to all circuitry outside of the memory cell array that supports the operation of the memory cell array 224, which may be a random access memory such as DRAM array. However, embodiments are not so limited, and it will be appreciated that the inventive aspects will be applicable to any type of memory descried herein. The memory peripheral circuitry includes, among other things, a row logic 218, a column logic 222, and control circuitry 216. The row logic 218 is connected to the memory cell array 224 by the row lines. The row logic 218 includes, among other things, latches, row decoder, and input buffers. The column logic 222 is connected to the memory cell array 224 by the column lines. The column logic 222 includes, among other things, sense amplifiers, column decoders, and output buffers.

Without limitation, by way of illustrative example of a read operation, a row address may be latched, decoded, and then buffered. A particular row line will, when selected, may be activated. This selects the entire row of the array. Since the row line may be long and loaded periodically with the capacitive memory cells, a buffer may be needed to drive the row line. The address is latched with signals from the control logic. After a particular row line is selected, the column address is used to decode which of the bits from the row are the addressed information. At this point, data can be read into or out of the array through the column decoder. Analogous addressing scheme may be employed for write operations.

The memory array die 220 can include a plurality of bit cells forming M by N array (the M and N can have the same number or different numbers without limitation), as illustrated in FIG. 2C. Each unit cell 250 of the bit cell of a DRAM includes one transistor 256 and one storage capacitor 252. The resistance between the transistor 256 and the storage capacitor 252 is represented by a resistor 254. The storage capacitor 252 is configured to store the charge representing the data bit, and the transistor 256 can connect the capacitor 252 to the bit line (BL) for the read and write operations. The array of the bit cells illustrated in FIG. 2C is merely illustrated as examples, and these numbers and types of the memory cells can be determined based on specific applications.

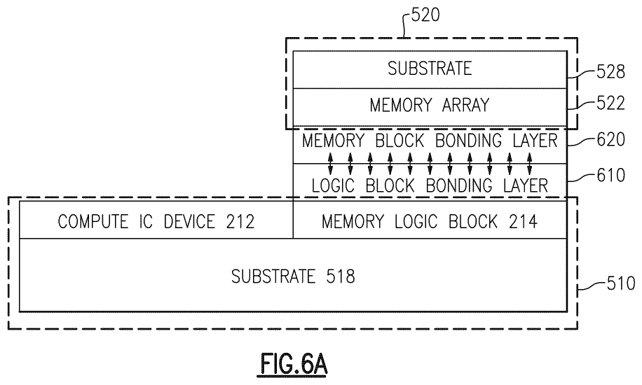

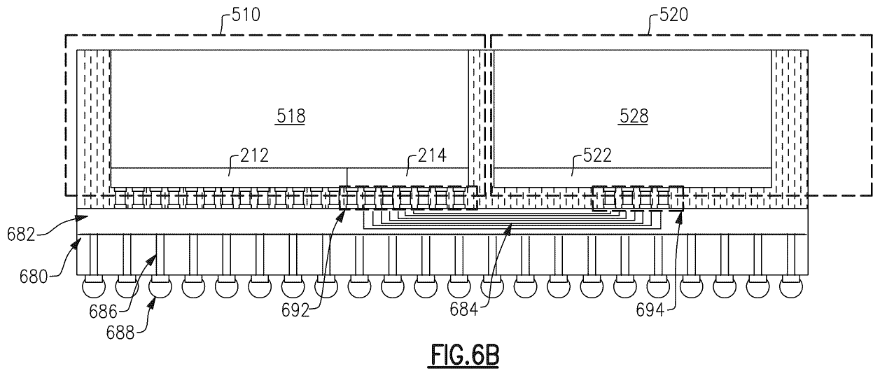

In some embodiments, the interconnect 130 can be a wire connection via physical interfaces fabricated on each of the unified logic die 210 and a memory array die 220. In some cases, the interconnect 130 can be 3 dimensional connections or 2.5 dimensional connections, as will be described with respect to FIGS. 6A and 6B.

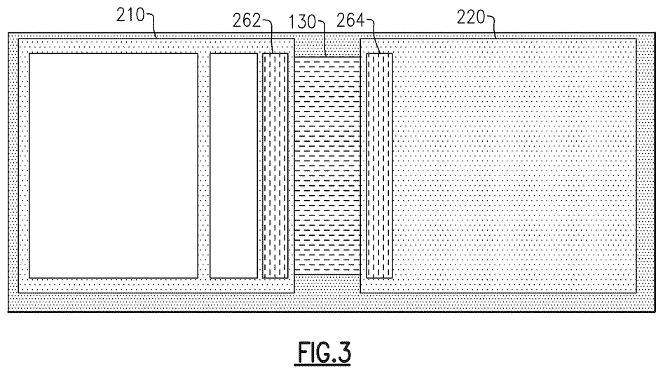

FIG. 3 illustrates an example of semiconductor IC device architecture 200 implementing 2 dimensional connection between the unified logic die 210 and the memory array die 220. In some embodiments, it can be desirable to have high speed (e.g., at least 1000 Mbit/s, high bandwidth (e.g., at least 10 Gbit/s), and/or low latency (e.g., less than 10 ns) communication between the unified logic die 210 and the memory array die 220. In some embodiments, the unified logic die 210 can include a region of high density contact interface 262. The memory array die 220 can include a region of high density contact interface 264. The semiconductor IC device architecture 200 can include interconnects 130 that can be used to connect the high density contact interface 262 and 264. In some embodiments, there may be little or no additional circuitry or functionality in the interconnects 130.

The semiconductor IC device architecture 200, as disclosed herein, addresses various needs in the conventional semiconductor IC device architecture 100 described herein. Advantageously, the semiconductor IC device architecture 200 can optimize the system level performance, power, area, and cost (PPAC).

### Modular Semiconductor IC Device Architecture

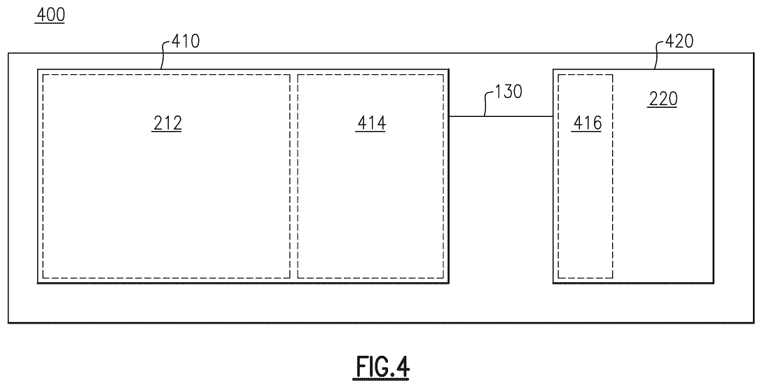

In some embodiments, the semiconductor IC device architecture, as disclosed herein, can provide a modular architecture configuration by selectively fabricating (e.g., monolithically fabricating) elements of the memory logic block on the unified logic die and the memory array die. FIG. 4 illustrates a diagram of a modular semiconductor IC device architecture 400, according to the embodiments disclosed herein. As illustrated in FIG. 4, the semiconductor IC device architecture 400 can include a unified logic die 410 and a memory system 420 communicatively coupled via an interconnect 130. The unified logic die 410 can include a compute IC device 212 and a first memory logic block 414. The memory system 420 can include a second memory logic block 416 and a memory array die 220.

In some embodiments, the electrical components of the memory logic block 214 (as illustrated in the above) can be selectively integrated on the first and second memory logic blocks 414 and 416. For example, the first memory logic block 414 can include one or more of the following peripheral circuitry designed for:
Access transistor;
Memory controller;
Memory interface;
Clock signal generator;
Read/Write operations;
Refresh (if the memory array die 220 includes DRAM) operations;
Power management operation;
Error correction code;

The second memory logic block 416 can include one or more of the following peripheral circuitry designed for:
Decoder;
Multiplexer; and
Sense amplifier.

The above configuration of the first and second memory logic blocks 414 and 416 is merely provided as examples, and the first and second memory logic blocks 414 and 416 can have various configurations based on specific applications.

### Multi-Dimensional Semiconductor IC Device Architecture

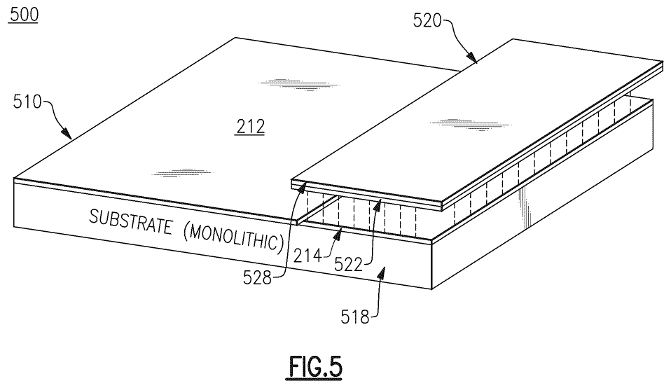

The integrated unified logic die and memory array die illustrated in FIGS. 2A and 4 can be heterogeneously integrated in various embodiments. FIG. 5 illustrates an example of semiconductor IC device architecture 500 in accordance with some embodiments disclosed herein. More specifically, the semiconductor IC device architecture 500 includes an integrated unified logic die 510 and memory array die 520.

As illustrated in FIG. 5, the integrated unified logic die 510 includes a compute IC device 212, the memory logic block 214, and substrate 518. Specifically, the compute IC device 212 and the memory logic block 214 are monolithically fabricated on the substrate 518. In some cases, the compute IC device 212 can be fabricated on a first portion of the substrate 518, and the memory logic block 214 can be fabricated on a second portion of the substrate 518.

As further illustrated in FIG. 5, the memory array die 520 includes the memory cell array 522 fabricated on one side of the substrate 528. In some embodiments, the memory array die 520 can be stacked on the integrated unified logic die 510 and physically integrated therewith by bonding. For example, the side of the substrate 528 that includes (e.g., fabricated) the memory array die 220 can be directly or indirectly bonded to the memory logic block 214, such that the memory array die 220 is stacked on the second portion of the substrate 518. In some embodiments, one or both of the substrates 518 and 528 can be thinned to reduce the form factor of the semiconductor IC device architecture. In some examples, the substrate 528 can be thinner than the substrate 518. In other examples, the substrates 518 and 528 can have the same thickness dimensions. In some embodiments, one or both of the unified logic die 510 and the memory array die 520 can include respective circuitry formed on a thinned substrate having a portion of a bulk substrate removed from a substrate on which the respective circuitry has been fabricated on.

As described herein, a “face” side of a die refers to the side on which circuit is formed, as opposed to the substrate side. In some embodiments, the memory array die 520 may be stacked face down on the unified logic die 510 that is facing up. In this configuration, the uppermost metallization layers of the memory array die 520 and the unified logic die 510 face each other. In these embodiments, the upper metallization layers of the memory array die 520 and the unified logic die 510 may be configured to directly contact and bonded to each other, e.g., by hybrid direct bonding.

In some other embodiments, the memory array die 520 may be stacked face up on the unified logic die 510 that is facing up. In this configuration, the uppermost metallization layers of the memory array die 520, and the unified logic die 510 are separated by the substrate of the memory array die 520. In these embodiments, the memory cell array of the memory array die 520 may be electrically connected to the memory peripheral circuit formed on the unified logic die 510, e.g., on the memory logic block 214, can be electrically connected by one or more through silicon vias (TSVs) formed through the substrate of the memory array die 520.

However, embodiments are not so limited, and in other embodiments, the memory array die 520 and the unified logic die 510 may be bonded using an intervening layer, e.g., an adhesive, and the electrical connections therebetween may be made using wire bonding.

In various embodiments, as will be illustrated in FIG. 6A, the memory array die and the unified logic die may be 3-dimensionally integrated, and as will be illustrated in FIG. 6B, the memory array die and the unified logic die may be 2.5-dimensionally integrated. It will be appreciated that in either configuration, the memory array die and the unified logic die may be integrated by direct bonding or using an adhesive layer.

### Multi-Dimensional Integration

In various embodiments, as will be illustrated in FIGS. 6A-6B, 3D stacking (shown in FIG. 6A) and 2.5D stacking (shown in FIG. 6B) can be used to connect the memory logic block 214 and the memory array die 220 (for example, as illustrated in FIG. 2A).

FIG. 6A illustrates an example of 3D stacking (e.g., 3D bonding) between the unified logic die 510 and the memory array die 520. The unified logic die 510 can include the compute IC device 212, the memory logic block 214, and a substrate 518, such that the compute IC device 212 and the memory logic block 214 are monolithically integrated on the substrate 518. The memory array die 520 can include the memory cell array 522 fabricated on the substrate 528. The unified logic die 510 and the memory array die 520 can be the same or similar to the unified logic die 210 and the memory array die 220, respectively, as illustrated in FIGS. 2A, 2B, and 5. In addition, unified logic die 510 and the memory array die 520 can be implemented as the semiconductor IC device architecture 400 illustrated in FIG. 4.

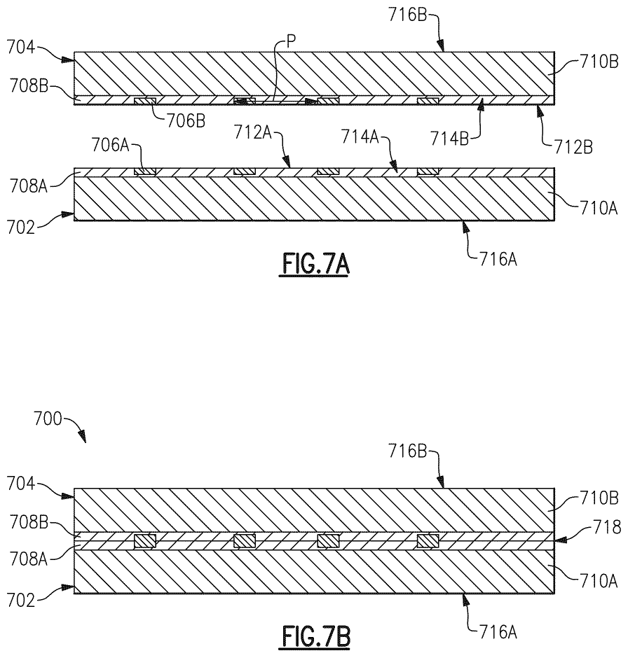

As shown in FIG. 6A, the memory array die 520 can be stacked on the memory logic block 214 of the unified logic die 510. In some embodiments, a logic block bonding layer 610 can be electrically coupled with the memory logic block 214, and the memory block bonding layer 620 can be electrically coupled with the memory cell array 522. The bonding layers 610 and 620 may correspond to the bonding layers 708A and 708B, respectively (FIG. 7A), and the detailed description of the bonding layers 610 and 620 (e.g., bonding layers 708A and 708B) are described with respect to FIGS. 7A and 7B. It will be appreciated that, while depicted as distinct layers, the bonding layers 610 and 620 may represent uppermost layers, e.g., metallization layers, of the memory array die 520 and the memory logic block 214, respectively. In such arrangements, it will be appreciated that the memory array die 520 and the unified logic die 510 include the respective bonding layers 610 and 620 that are direct bonded, e.g., hybrid direct bonded. However, embodiments are not so limited and in other embodiments, the bonding layers 610 and 620 may be separately formed layers on top of the memory array die 520 and the memory logic block 214, respectively. When formed as separate layers, the bonding layers 610 and 620 may or may not include adhesive and/or interconnect structures.

In alternative embodiments, the memory cell array 522 and the memory logic block 214 can be connected via micro bumps (not shown in FIG. 6A). In these embodiments, the bonding layers 610 and 620 can have micro bumps with a pitch of at least 10 μm. Thus, the memory cell array 522 and the memory logic block 214 are connected via the micro bumps included in corresponding bonding layer 610 and 620.

In some cases, the 3D stacking (3D bonding) can be applied in various levels of integration. For example, when a plurality of unified logic dies 510 are fabricated on a wafer, the memory array die 520 can bond with corresponding unified logic die 510 (e.g., the memory logic block 214) via the 3D stacking, as disclosed herein. In another example, when a plurality of unified logic dies 510 are fabricated on a first wafer and that a plurality of memory array dies 520 are fabricated on a second wafer, the first and second wafer can be bonded (after an alignment between the first and second wafers) via the 3D stacking, as disclosed herein.

As described elsewhere herein, while FIG. 6A depicts the memory array die 520 as facing down on the unified logic die 510, embodiments are not so limited. In other embodiments, the memory array die 520 may be facing up, and the electrical connections to the underlying memory logic block 214 may be formed using through silicon vias extending through the substrate 528.

While the illustrated memory array die 520 is depicted as having similar footprint as the memory logic block 214, embodiments are not so limited, and the memory array die 520 may be larger or smaller.

FIG. 6B illustrates an example of 2.5D stacking (e.g., 2.5D bonding) between the unified logic die 510 and the memory array die 520. The unified logic die 510 can include the compute IC device 212 and the memory logic block 214 formed on a substrate 518, such that the compute IC device 212 and the memory logic block 214 are monolithically integrated on the substrate 518. The memory array die 520 can include the memory cell array 522 fabricated on the substrate 528. The unified logic die 510 and the memory array die 520 described in FIG. 6B can be the same or have similar components to the unified logic die 210 and the memory array die 220, respectively, as those described with respect to FIGS. 2A, 2B, and 5. In addition, the unified logic die 510 and the memory array die 520 can be implemented as the semiconductor IC device architecture 400 illustrated in FIG. 4.

As illustrated in FIG. 6B, the unified logic die 510 and the memory array die 520 are electrically coupled via an interposer 680. More specifically, the memory logic block 214 is electrically connected with the memory cell array 522 included in the memory array die 520 via the interconnects 684 embedded in an interposer 680. The interposer 680 may include an interposer circuit layer 682. In some embodiments, the interposer circuit layer 682 is positioned on top of the interposer 680 to face the memory array die 520 and the unified logic die 520. The unified logic die 510 and the memory array die 520 are bonded with the interposer 680. In some embodiments, the interposer 680 can have embedded interconnects 684, such as conductive traces, to connect the memory logic block 214 and the memory array die 520. For example, the terminals (or pins) 692 connected to the memory logic block 214 are electrically coupled to the terminals (or pins) 694 of the memory array die 520 via the interconnects 684. In some examples, the pattern of the interconnects 684 can be specifically designed to connect the terminals (or pins) 692 and the terminals (or pins) 694. In some cases, the interconnects 684 can be referred to as an interconnection bridge, such as conducting wires embedded in the interposer substrate 682. The

It will be appreciated that, while in the illustrated embodiment, the unified logic die 510 and the memory array die 520 are stacked face down on the interposer circuit layer 682, embodiments are not so limited. In other embodiments, the unified logic die 510 and the memory array die 520 may be stacked up with through silicon vias formed through the respective substrates to connect to the interposer 680.

It will be further appreciated that, while not shown, the memory array die 520 and the unified logic die 510 may be directly bonded, e.g., hybrid direct bonded, to the interposer 680.

In some embodiments, the connections, such as TSV 686 can be extended to a bottom of the interposer 680 to provide access to external components, e.g., other chips or a board. For example, the interposer can provide connecting points 688 that connect with the unified logic die 510 and the memory array die 520. The interposer 680 can be composed of silicon or any suitable organic materials, such as a semiconductor (e.g., silicon), dielectric (e.g., glass), or ceramic. In some embodiments, the interposer 680 can have low parasitic material (e.g., materials having low parasitic inductance, resistance, and capacitance). In some embodiments, the interposer 680 can have bridge configuration, having low parasitic inductance, resistance, and capacitance.

### 3D Bonding Structure

The 3D bonding (e.g., 3D stacking) disclosed herein relates to directly bonded structures (for example, as illustrated in FIG. 6A) in which two or more elements can be directly bonded to one another without an intervening adhesive. Such processes and structures can also be referred to herein as “direct bonding” processes or “directly bonded” structures. Direct bonding can involve bonding of one material on one element and one material on the other element (also referred to as “uniform” direct bond herein), where the materials on the different elements need not be the same, without traditional adhesive materials. Direct bonding can also involve the bonding of multiple materials on one element to multiple materials on the other element (e.g., hybrid bonding).

In some implementations (not illustrated), each bonding layer has one material. In these uniform direct bonding processes, only one material on each element is directly bonded. Example uniform direct bonding processes include the ZIBOND® techniques commercially available from Adeia of San Jose, CA. The materials of opposing bonding layers on the different elements can be the same or different, and may comprise elemental or compound materials. For example, in some embodiments, nonconductive bonding layers can be blanket deposited over the base substrate portions without being patterned with conductive features (e.g., without pads). In other embodiments, the bonding layers can be patterned on one or both elements, and can be the same or different from one another, but one material from each element is directly bonded without adhesive across surfaces of the elements (or across the surface of the smaller element if the elements are differently-sized). In another implementation of uniform direct bonding, one or both of the nonconductive bonding layers may include one or more conductive features, but the conductive features are not involved in the bonding. For example, in some implementations, opposing nonconductive bonding layers can be uniformly directly bonded to one another, and through substrate vias (TSVs) can be subsequently formed through one element after bonding to provide electrical communication to the other element.

In various embodiments, the bonding layers 708A and/or 708B (e.g., 610 and/or 620 illustrated in FIG. 6B) can comprise a non-conductive material such as a dielectric material or an undoped semiconductor material, such as undoped silicon, which may include native oxide. Suitable dielectric bonding surface or materials for direct bonding include but are not limited to inorganic dielectrics, such as silicon oxide, silicon nitride, or silicon oxynitride, or can include carbon, such as silicon carbide, silicon oxycarbonitride, low K dielectric materials, SiCOH dielectrics, silicon carbonitride or diamond-like carbon or a material comprising a diamond surface. Such carbon-containing ceramic materials can be considered inorganic, despite the inclusion of carbon. In some embodiments, the dielectric materials at the bonding surface do not comprise polymer materials, such as epoxy (e.g., epoxy adhesives, cured epoxies, or epoxy composites such as FR-4 materials), resin or molding materials.

In other embodiments, the bonding layers can comprise an electrically conductive material, such as a deposited conductive oxide material, e.g., indium tin oxide (ITO), as disclosed in U.S. Provisional Patent Application No. 63/524,564, filed Jun. 30, 2023, the entire contents of which is incorporated by reference herein in its entirety for providing examples of conductive bonding layers without shorting contacts through the interface.

In direct bonding, first and second elements can be directly bonded to one another without an adhesive, which is different from a deposition process and results in a structurally different interface compared to that produced by deposition. In one application, a width of the first element in the bonded structure is similar to a width of the second element. In some other embodiments, a width of the first element in the bonded structure is different from a width of the second element. The width or area of the larger element in the bonded structure may be at least 10% larger than the width or area of the smaller element. Further, the interface between directly bonded structures, unlike the interface beneath deposited layers, can include a defect region in which nanometer-scale voids (nanovoids) are present. The nanovoids may be formed due to activation of one or both of the bonding surfaces (e.g., exposure to a plasma, explained below).

The bond interface between non-conductive bonding surfaces can include a higher concentration of materials from the activation and/or last chemical treatment processes compared to the bulk of the bonding layers. For example, in embodiments that utilize a nitrogen plasma for activation, a nitrogen concentration peak can be formed at the bond interface. In some embodiments, the nitrogen concentration peak may be detectable using secondary ion mass spectroscopy (SIMS) techniques. In various embodiments, for example, a nitrogen termination treatment (e.g., exposing the bonding surface to a nitrogen-containing plasma) can replace OH groups of a hydrolyzed (OH-terminated) surface with NH₂ molecules, yielding a nitrogen-terminated surface. In embodiments that utilize an oxygen plasma for activation, an oxygen concentration peak can be formed at the bond interface between non-conductive bonding surfaces. In some embodiments, the bond interface can comprise silicon oxynitride, silicon oxycarbonitride, or silicon carbonitride. The direct bond can comprise a covalent bond, which is stronger than van Der Waals bonds. The bonding layers can also comprise polished surfaces that are planarized to a high degree of smoothness.

In direct bonding processes, such as uniform direct bonding and hybrid bonding, two elements are bonded together without an intervening adhesive. In non-direct bonding processes that utilize an adhesive, an intervening material is typically applied to one or both elements to effectuate a physical connection between the elements. For example, in some adhesive-based processes, a flowable adhesive (e.g., an organic adhesive, such as an epoxy), which can include conductive filler materials, can be applied to one or both elements and cured to form the physical (rather than chemical or covalent) connection between elements. Typical organic adhesives lack strong chemical or covalent bonds with either element. In such processes, the connections between the elements are weak and/or readily reversed, such as by reheating or defluxing.

By contrast, direct bonding processes join two elements by forming strong chemical bonds (e.g., covalent bonds) between opposing nonconductive materials. For example, in direct bonding processes between nonconductive materials, one or both nonconductive surfaces of the two elements are planarized and chemically prepared (e.g., activated and/or terminated) such that when the elements are brought into contact, strong chemical bonds (e.g., covalent bonds) are formed, which are stronger than Van der Waals or hydrogen bonds. In some implementations (e.g., between opposing dielectric surfaces, such as opposing silicon oxide surfaces), the chemical bonds can occur spontaneously at room temperature upon being brought into contact. In some implementations, the chemical bonds between opposing non-conductive materials can be strengthened after annealing the elements.

As noted above, hybrid bonding is a species of direct bonding in which both non-conductive features directly bond to non-conductive features, and conductive features directly bond to conductive features of the elements being bonded. The non-conductive bonding materials and interface can be as described above, while the conductive bond can be formed, for example, as a direct metal-to-metal connection. In conventional metal bonding processes, a fusible metal alloy (e.g., solder) can be provided between the conductors of two elements, heated to melt the alloy, and cooled to form the connection between the two elements. The resulting bond often evinces sharp interfaces with conductors from both elements, and is subject to reversal by reheating. By way of contrast, direct metal bonding as employed in hybrid bonding does not require melting or an intermediate fusible metal alloy, and can result in strong mechanical and electrical connections, often demonstrating interdiffusion of the bonded conductive features with grain growth across the bonding interface between the elements, even without the much higher temperatures and pressures of thermocompression bonding.

FIGS. 7A and 7B schematically illustrate cross-sectional side views of first and second elements 702, 704 prior to and after, respectively, a process for forming a 3D stacking (e.g., 3D bonding) structure illustrated in FIGS. 5 and 6A, and more particularly a hybrid bonded structure, according to some embodiments. For example, the first and second elements 702 and 704 can also refer to the memory logic block 214 and the memory array die 220, respectively, according to some embodiments disclosed herein. In FIG. 7B, a bonded structure 700 comprises the first and second elements 702 and 704 (the memory logic block 214 and the memory array die 220, respectively) that are directly bonded to one another at a bond interface 718 without an intervening adhesive. Conductive features 706A of a first element 702 may be electrically connected to corresponding conductive features 706B of a second element 704. In the illustrated hybrid bonded structure 700, the conductive features 706A are directly bonded to the corresponding conductive features 706B without intervening solder or conductive adhesive.

The conductive features 706A and 706B of the illustrated embodiment are embedded in, and can be considered part of, a first bonding layer 708A of the first element 702 and a second bonding layer 708B of the second element 704, respectively. Field regions of the bonding layers 708A, 708B extend between and partially or fully surround the conductive features 706A, 706B. The bonding layers 708A, 708B can comprise layers of non-conductive materials suitable for direct bonding, as described above, and the field regions are directly bonded to one another without an adhesive. The non-conductive bonding layers 708A, 708B can be disposed on respective front sides 714A, 714B of base substrate portions 710A, 710B.

The first and second elements 702, 704 can comprise microelectronic elements, such as semiconductor elements, including, for example, integrated device dies, wafers, passive devices, discrete active devices such as power switches, MEMS, etc. In some embodiments, the base substrate portion can comprise a device portion, such as a bulk semiconductor (e.g., silicon) portion of the elements 702, 704, and back-end-of-line (BEOL) interconnect layers over such semiconductor portions. The bonding layers 708A, 708B can be provided as part of such BEOL layers during device fabrication, as part of redistribution layers (RDL), or as specific bonding layers added to existing devices, with bond pads extending from underlying contacts. Active devices and/or circuitry can be patterned and/or otherwise disposed in or on the base substrate portions 710A, 710B, and can electrically communicate with at least some of the conductive features 706A, 706B. Active devices and/or circuitry can be disposed at or near the front sides 714A, 714B of the base substrate portions 710A, 710B, and/or at or near opposite backsides 716A, 716B of the base substrate portions 710A, 710B. In other embodiments, the base substrate portions 710A, 710B may not include active circuitry, but may instead comprise dummy substrates, passive interposers, passive optical elements (e.g., glass substrates, gratings, lenses), etc. The bonding layers 708A, 708B are shown as being provided on the front sides of the elements, but similar bonding layers can be additionally or alternatively provided on the back sides of the elements.

In some embodiments, the base substrate portions 710A, 710B can have significantly different coefficients of thermal expansion (CTEs), and bonding elements that include such different based substrate portions can form a heterogenous bonded structure. The CTE difference between the base substrate portions 710A and 710B, and particularly between bulk semiconductor (typically single crystal) portions of the base substrate portions 710A, 710B, can be greater than 5 ppm/° C. or greater than 10 ppm/° C. For example, the CTE difference between the base substrate portions 710A and 710B can be in a range of 5 ppm/° C. to 100 ppm/° C., 5 ppm/° C. to 40 ppm/° C., 10 ppm/° C. to 100 ppm/° C., or 10 ppm/° C. to 40 ppm/° C.

In some embodiments, one of the base substrate portions 710A, 710B can comprise optoelectronic single crystal materials, including perovskite materials, that are useful for optical piezoelectric or pyroelectric applications, and the other of the base substrate portions 710A, 710B comprises a more conventional substrate material. For example, one of the base substrate portions 710A, 710B comprises lithium tantalate (LiTaO₃) or lithium niobate (LiNbO₃), and the other one of the base substrate portions 710A, 710B comprises silicon (Si), quartz, fused silica glass, sapphire, or a glass. In other embodiments, one of the base substrate portions 710A, 710B comprises a III-V single semiconductor material, such as gallium arsenide (GaAs) or gallium nitride (GaN), and the other one of the base substrate portions 710A, 710B can comprise a non-III-V semiconductor material, such as silicon (Si), or can comprise other materials with similar CTE, such as quartz, fused silica glass, sapphire, or a glass. In still other embodiments, one of the base substrate portions 710A, 710B comprises a semiconductor material and the other of the base substrate portions 710A, 710B comprises a packaging material, such as a glass, organic or ceramic substrate.

In some arrangements, the first element 702 can comprise a singulated element, such as a singulated integrated device die. In other arrangements, the first element 702 can comprise a carrier or substrate (e.g., a semiconductor wafer) that includes a plurality (e.g., tens, hundreds, or more) of device regions that, when singulated, forms a plurality of integrated device dies, though in other embodiments such a carrier can be a package substrate or a passive or active interposer. Similarly, the second element 704 can comprise a singulated element, such as a singulated integrated device die. In other arrangements, the second element 704 can comprise a carrier or substrate (e.g., a semiconductor wafer). The embodiments disclosed herein can accordingly apply to wafer-to-wafer (W2 W), die-to-die (D2D), or die-to-wafer (D2 W) bonding processes. In W2 W processes, two or more wafers can be directly bonded to one another (e.g., direct hybrid bonded) and singulated using a suitable singulation process. After singulation, side edges of the singulated structure (e.g., the side edges of the two bonded elements) can be substantially flush (substantially aligned x-y dimensions) and/or the edges of the bonding interfaces for both bonded and singulated elements can be coextensive, and may include markings indicative of the common singulation process for the bonded structure (e.g., saw markings if a saw singulation process is used).

While only two elements 702, 704 are shown, any suitable number of elements can be stacked in the bonded structure 700. For example, a third element (not shown) can be stacked on the second element 704, a fourth element (not shown) can be stacked on the third element, and so forth. In such implementations, through substrate vias (TSVs) can be formed to provide vertical electrical communication between and/or among the vertically-stacked elements. Additionally or alternatively, one or more additional elements (not shown) can be stacked laterally adjacent one another along the first element 702. In some embodiments, a laterally stacked additional element may be smaller than the second element. In some embodiments, the bonded structure can be encapsulated with an insulating material, such as an inorganic dielectric (e.g., silicon oxide, silicon nitride, silicon oxynitrocarbide, etc.). One or more insulating layers can be provided over the bonded structure. For example, in some implementations, a first insulating layer can be conformally deposited over the bonded structure, and a second insulating layer (which may include be the same material as the first insulating layer, or a different material) can be provided over the first insulating layer.

To effectuate direct bonding between the bonding layers 708A, 708B, the bonding layers 708A, 708B can be prepared for direct bonding. Non-conductive bonding surfaces 712A, 712B at the upper or exterior surfaces of the bonding layers 708A, 708B can be prepared for direct bonding by polishing, for example, by chemical mechanical polishing (CMP). The roughness of the polished bonding surfaces 712A, 712B can be less than 30 Å rms. For example, the roughness of the bonding surfaces 712A and 712B can be in a range of about 0.1 Å rms to 15 Å rms, 0.5 Å rms to 10 Å rms, or 1 Årms to 5 Å rms. Polishing can also be tuned to leave the conductive features 706A, 706B recessed relative to the field regions of the bonding layers 708A, 708B.

Preparation for direct bonding can also include cleaning and exposing one or both of the bonding surfaces 712A, 712B to a plasma and/or etchants to activate at least one of the surfaces 712A, 712B. In some embodiments, one or both of the surfaces 712A, 712B can be terminated with a species after activation or during activation (e.g., during the plasma and/or etch processes). Without being limited by theory, in some embodiments, the activation process can be performed to break chemical bonds at the bonding surface(s) 712A, 712B, and the termination process can provide additional chemical species at the bonding surface(s) 712A, 712B that alters the chemical bond and/or improves the bonding energy during direct bonding. In some embodiments, the activation and termination are provided in the same step, e.g., a plasma to activate and terminate the surface(s) 712A, 712B. In other embodiments, one or both of the bonding surfaces 712A, 712B can be terminated in a separate treatment to provide the additional species for direct bonding. In various embodiments, the terminating species can comprise nitrogen. For example, in some embodiments, the bonding surface(s) 712A, 712B can be exposed to a nitrogen-containing plasma. Other terminating species can be suitable for improving bonding energy, depending upon the materials of the bonding surfaces 712A, 712B. Further, in some embodiments, the bonding surface(s) 712A, 712B can be exposed to fluorine. For example, there may be one or multiple fluorine concentration peaks at or near a bond interface 718 between the first and second elements 702, 704. Typically, fluorine concentration peaks occur at interfaces between material layers. Additional examples of activation and/or termination treatments may be found in U.S. Pat. No. 9,391,143 at Col. 5, line 55 to Col. 7, line 3; Col. 8, line 52 to Col. 9, line 45; Col. 10, lines 24-36; Col. 11, lines 24-32, 42-47, 52-55, and 60-64; Col. 12, lines 3-14, 31-33, and 55-67; Col. 14, lines 38-40 and 44-50; and 10,434,749 at Col. 4, lines 41-50; Col. 5, lines 7-22, 39, 55-61; Col. 8, lines 25-31, 35-40, and 49-56; and Col. 12, lines 46-61, the activation and termination teachings of which are incorporated by reference herein.

Thus, in the directly bonded structure 700, the bond interface 718 between two non-conductive materials (e.g., the bonding layers 708A, 708B) can comprise a very smooth interface with higher nitrogen (or other terminating species) content and/or fluorine concentration peaks at the bond interface 718. In some embodiments, the nitrogen and/or fluorine concentration peaks may be detected using various types of inspection techniques, such as SIMS techniques. The polished bonding surfaces 712A and 712B can be slightly rougher (e.g., about 1 Å rms to 30 Å rms, 3 Å rms to 20 Å rms, or possibly rougher) after an activation process. In some embodiments, activation and/or termination can result in slightly smoother surfaces prior to bonding, such as where a plasma treatment preferentially erodes high points on the bonding surface.

The non-conductive bonding layers 708A and 708B can be directly bonded to one another without an adhesive. In some embodiments, the elements 702, 704 are brought together at room temperature, without the need for application of a voltage, and without the need for application of external pressure or force beyond that used to initiate contact between the two elements 702, 704. Contact alone can cause direct bonding between the non-conductive surfaces of the bonding layers 708A, 708B (e.g., covalent dielectric bonding). Subsequent annealing of the bonded structure 700 can cause the conductive features 706A, 706B to directly bond.

In some embodiments, prior to direct bonding, the conductive features 706A, 706B are recessed relative to the surrounding field regions, such that a total gap between opposing contacts after dielectric bonding and prior to anneal is less than 15 nm, or less than 10 nm. Because the recess depths for the conductive features 706A and 706B can vary across each element, due to process variation, the noted gap can represent a maximum or an average gap between corresponding conductive features 706A, 706B of two joined elements (prior to anneal). Upon annealing, the conductive features 706A and 706B can expand and contact one another to form a metal-to-metal direct bond.

During annealing, the conductive features 706A, 706B (e.g., metallic material) can expand while the direct bonds between surrounding non-conductive materials of the bonding layers 708A, 708B resist separation of the elements, such that the thermal expansion increases the internal contact pressure between the opposing conductive features. Annealing can also cause metallic grain growth across the bonding interface, such that grains from one element migrate across the bonding interface at least partially into the other element, and vice versa. Thus, in some hybrid bonding embodiments, opposing conductive materials are joined without heating above the conductive materials' melting temperature, such that bonds can form with lower anneal temperatures compared to soldering or thermocompression bonding.

In various embodiments, the conductive features 706A, 706B can comprise discrete pads, contacts, electrodes, or traces at least partially embedded in the non-conductive field regions of the bonding layers 708A, 708B. In some embodiments, the conductive features 706A, 706B can comprise exposed contact surfaces of TSVs (e.g., through silicon vias).

As noted above, in some embodiments, in the elements 702, 704 of FIG. 7A prior to direct bonding, portions of the respective conductive features 706A and 706B can be recessed below the non-conductive bonding surfaces 712A and 712B, for example, recessed by less than 30 nm, less than 20 nm, less than 15 nm, or less than 10 nm, for example, recessed in a range of 2 nm to 20 nm, or in a range of 4 nm to 10 nm. Due to process variation, both dielectric thickness and conductor recess depths can vary across an element. Accordingly, the above recess depth ranges may apply to individual conductive features 706A, 706B or to average depths of the recesses relative to local non-conductive field regions. Even for an individual conductive feature 706A, 706B, the vertical recess can vary across the feature, and so can be measured at or near the lateral middle or center of the cavity in which a given conductive feature 706A, 706B is formed, or can be measured at the sides of the cavity.

Beneficially, the use of hybrid bonding techniques (such as Direct Bond Interconnect, or DBI®, techniques commercially available from Adeia of San Jose, CA) can enable high density of connections between conductive features 706A, 706B across the direct bond interface 718 (e.g., small or fine pitches for regular arrays).

In some embodiments, a pitch p of the conductive features 706A, 706B, such as conductive traces embedded in the bonding surface of one of the bonded elements, may be less than 40 μm, less than 20 μm, less than 10 μm, less than 5 μm, less than 2 μm, or even less than 1 μm. For some applications, the ratio of the pitch of the conductive features 706A and 706B to one of the lateral dimensions (e.g., a diameter) of the bonding pad is less than is less than 20, or less than 10, or less than 5, or less than 3 and sometimes desirably less than 2. In various embodiments, the conductive features 706A and 706B and/or traces can comprise copper or copper alloys, although other metals may be suitable, such as nickel, aluminum, or alloys thereof. The conductive features disclosed herein, such as the conductive features 706A and 706B, can comprise fine-grain metal (e.g., a fine-grain copper). Further, a major lateral dimension (e.g., a pad diameter) can be small as well, e.g., in a range of about 0.25 μm to 30 μm, in a range of about 0.25 μm to 5 μm, or in a range of about 0.5 μm to 5 μm.

For hybrid bonded elements 702, 704, as shown, the orientations of one or more conductive features 706A, 706B from opposite elements can be opposite to one another. As is known in the art, conductive features in general can be formed with close to vertical sidewalls, particularly where directional reactive ion etching (RIE) defines the conductor sidewalls either directly though etching the conductive material or indirectly through etching surrounding insulators in damascene processes. However, some slight taper to the conductor sidewalls can be present, wherein the conductor becomes narrower farther away from the surface initially exposed to the etch. The taper can be even more pronounced when the conductive sidewall is defined directly or indirectly with isotropic wet or dry etching. In the illustrated embodiment, at least one conductive feature 706B in the bonding layer 708B (and/or at least one internal conductive feature, such as a BEOL feature) of the upper element 704 may be tapered or narrowed upwardly, away from the bonding surface 712B. By way of contrast, at least one conductive feature 706A in the bonding layer 708A (and/or at least one internal conductive feature, such as a BEOL feature) of the lower element 702 may be tapered or narrowed downwardly, away from the bonding surface 712A. Similarly, any bonding layers (not shown) on the backsides 716A, 716B of the elements 702, 704 may taper or narrow away from the backsides, with an opposite taper orientation relative to front side conductive features 706A, 706B of the same element.

As described above, in an anneal phase of hybrid bonding, the conductive features 706A, 706B can expand and contact one another to form a metal-to-metal direct bond. In some embodiments, the materials of the conductive features 706A, 706B of opposite elements 702, 704 can interdiffuse during the annealing process. In some embodiments, metal grains grow into each other across the bond interface 718. In some embodiments, the metal is or includes copper, which can have grains oriented along the 111 crystal plane for improved copper diffusion across the bond interface 718. In some embodiments, the conductive features 706A and 706B may include nanotwinned copper grain structure, which can aid in merging the conductive features during anneal. There is substantially no gap between the non-conductive bonding layers 708A and 708B at or near the bonded conductive features 706A and 706B. In some embodiments, a barrier layer may be provided under and/or laterally surrounding the conductive features 706A and 706B (e.g., which may include copper). In other embodiments, however, there may be no barrier layer under the conductive features 706A and 706B.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number, respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the novel apparatus, methods, and systems described herein may be embodied in a variety of other forms; furthermore, various omissions, substitutions, and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

1. A semiconductor integrated circuit (IC) device comprising:
a unified logic die comprising:
a compute logic block; and
a memory logic block monolithically integrated with the compute logic block on a same substrate, the memory logic block comprising a memory peripheral circuitry configured for controlling a memory cell array external to the unified logic die; and
a memory array die heterogeneously integrated with the unified logic die, the memory array die comprising the memory cell array, the memory array die communicatively coupled with the memory logic block.

2. The semiconductor IC device of claim 1, wherein the memory logic block and the logic block transmit and receive data from each other directly without encoding or decoding using a physical layer (PHY).

3. The semiconductor IC device of claim 1, wherein the compute logic block comprises a central processing unit (CPU), a graphic processing unit (GPU), a tensor processing unit (TPU), or a system on chip (SOC).

4. The semiconductor IC device of claim 3, wherein the compute logic block and the memory logic block comprise respective complementary metal oxide semiconductor (CMOS) circuitry that are co-fabricated at a same process technology node and have at least one common critical dimension.

5. The semiconductor IC device of claim 1, wherein one or both of the unified logic die and the memory array die comprise respective circuitry formed on a thinned substrate having a portion of a bulk substrate removed from a substrate on which the respective circuitry has been fabricated on.

6. The semiconductor IC device of claim 1, wherein the memory array die and the unified logic die are three-dimensionally (3D) integrated by vertically stacking one over the other.

7. The semiconductor IC device of claim 1, wherein the memory array die and the unified logic die are 2.5 dimensionally (2.5D) integrated through an interposer.

8. The semiconductor IC device of claim 1, wherein the memory peripheral circuitry comprises at least a memory controller circuitry for accessing the memory cell array during read and write operations.

9. The semiconductor IC device of claim 8, wherein the memory peripheral circuitry further comprises circuitry adapted to serve one or more functionalities including memory interfacing, clock generation, timing signal generation, memory power management and error correction.

10. The semiconductor IC device of claim 8, wherein the memory peripheral circuitry comprises row or column access transistors, decoders, multiplexers, and sense amplifiers.

11. The semiconductor IC device of claim 1, wherein the memory cell array comprises a volatile memory cell array.

12. The semiconductor IC device of claim 11, wherein the volatile memory cell array comprises a dynamic random access memory (DRAM) array.

13. The semiconductor IC device of claim 1, wherein the memory cell array comprises a nonvolatile memory cell array.

14. The semiconductor IC device of claim 13, wherein the nonvolatile memory cell array comprises a flash memory cell array, a magnetoresistive random access memory (MRAM) array, a resistive random access memory (RRAM) array, a ferroelectric random access memory (FRAM) array, or a phase-change memory (PCM) array.

15. A semiconductor integrated circuit (IC) device comprising:
a unified logic die comprising:
a compute logic block; and
a memory logic block monolithically integrated with the compute logic block on a same substrate, the memory logic block comprising a memory peripheral circuitry configured for controlling a memory cell array external to the unified logic die; and
a memory array die, the memory array die comprising the memory cell array,
wherein the memory array die and the unified logic die are three-dimensionally (3D) integrated by stacking one over the other.

16. The semiconductor IC device of claim 15, wherein the memory array die and the unified logic die are directly bonded without an intervening layer.

17. The semiconductor IC device of claim 16, wherein the memory array die and the unified logic die are three-dimensionally (3D) integrated by hybrid direct bonding an uppermost interconnect layer of the memory array die to an uppermost interconnect layer of unified logic die.

18. The semiconductor IC device of claim 15, wherein the compute logic block comprises a central processing unit (CPU), a graphic processing unit (GPU), a tensor processing unit (TPU), or a system on chip (SOC).

19. The semiconductor IC device of claim 12, wherein one or both of the unified logic die and the memory array die comprises respective circuitry formed on a thinned substrate having a portion of a bulk substrate removed from a substrate on which the respective circuitry has been fabricated on.

20. The semiconductor IC device of claim 12, wherein the memory logic block comprises at least a memory controller circuitry for accessing the memory cell array during read and write operations.

21. The semiconductor IC device of claim 15, wherein the memory logic block and the logic block transmit and receive data from each other directly without encoding or decoding using a physical layer (PHY).

22.-37. (canceled)
